(19) United States
(12) Patent Application Publication
(10) Pub. No.: US 2005/0128706 A1
(43) Pub. Date: Jun. 16, 2005

(54) Power module with heat exchange

(75) Inventors: Douglas K. Maly, Canton, MI (US); Kanghua Chen, Canton, MI (US); Ajay V. Patwardhan, Canton, MI (US); Sayeed Ahmed, Canton, MI (US); Pablo Rodriguez, Dearborn, MI (US); Gerardo Jimenez, Southgate, MI (US)

Correspondence Address: SEED INTELLECTUAL PROPERTY LAW GROUP PLLC, 701 FIFTH AVE, SUITE 6300, SEATTLE, WA, 98104-7092, US

(73) Assignee: Ballard Power Systems Corporation, Dearborn, MI (US)

(21) Appl. No.: 10/738,926

(22) Filed: Dec. 16, 2003

(51) Int. Cl. H05K 7/20

(52) U.S. Cl. 361/699

(57) ABSTRACT

A power module comprises first and second substrates carrying semiconductor devices and coupled to respective pluralities of heat exchange members without intervening thermally insulative structures. One or more heat exchange loops circulate a heat exchange medium thermally coupled to the heat exchange members. Substrates may function as integral bus bars.

### BACKGROUND OF THE INVENTION

1. Field of the Invention

This disclosure generally relates to electrical power converters, and more particularly to an architecture suitable for use in electrical power modules.

2. Description of the Related Art

Power modules are typically self-contained units that include a converter to transform and/or condition power from one or more power sources for supplying power to one or more loads. Converters commonly referred to as “inverters” transform direct current (DC) to alternating current (AC), for use in supplying power to an AC load. Converters commonly referred to as a “rectifiers” transform AC to DC. Converters commonly referred to as “DC/DC converters” step up or step down a DC voltage. An appropriately configured and operated converter may perform any one or more of these functions. The term “converter” is commonly applies to all converters whether inverters, rectifiers and/or DC/DC converters.

A large variety of applications require power transformation and/or conditioning. For example, a DC power source such as a fuel cell system, battery and/or ultracapacitor may supply DC power, which must be inverted to provide power to an AC load such as a three-phase AC motor in an electric or hybrid vehicle. A photo-voltaic array may produce DC power which must be inverted to provide or export AC power to a power grid of a utility. An AC power source such as a power grid or micro-turbine may need to be rectified to provide power to a DC load such as a tool, machine or appliance. A high voltage DC source may need to be stepped down to supply a low voltage load, or a low voltage DC source may need to be stepped up to supply a high voltage load. Other applications will become apparent to those of skill in the art based on the teachings herein.

Power modules typically employ transistors, diodes and other components that generate substantial heat during operation, particularly when operating at high loads. Excessive heat can cause the components to under perform or even fail if not adequately addressed. Conventional power module structures employ various electrically insulating layers for electrically insulating the various components from one another and from the exterior of the power module. For example, components are typically mounted on direct bond copper (DBC) or direct bond aluminum (DBA) substrates, which comprise a ceramic substrate with metal foil fused on both sides. Unadvantageously, these electrically insulating layers also tend to be thermally insulating, significantly decreasing the ability to transfer heat away from the electronics.

A power module with enhanced heat transfer characteristics is thus desirable.

### SUMMARY OF THE INVENTION

In one aspect, a power module comprises a housing of electrically insulative material, the housing comprising an interior and an exterior; a first plurality of heat exchange members coupled to the housing; a second plurality of heat exchange members coupled to the housing and electrically isolated from the first plurality of heat exchange members; a first substrate of electrically and thermally conductive material received in the interior of the housing and thermally coupled to the first plurality of heat exchange members without any intervening thermally insulative structures; a second substrate of electrically and thermally conductive material received in the interior of the housing and thermally coupled to the second plurality of heat exchange members without any intervening thermally insulative structures, the second substrate electrically isolated from the first substrate; a first set of semiconductor devices each comprising at least a first terminal and a second terminal, each of the semiconductor devices of the first set surface mounted to the first substrate to electrically couple the first terminal of the semiconductor device to the first substrate and to thermally couple the semiconductor devices to the first plurality of heat exchange members via the first substrate; and a second set of semiconductor devices each comprising at least a first terminal and a second terminal, each of the semiconductor devices of the second set surface mounted to the second substrate to electrically couple the first terminal of the semiconductor device to the second substrate and to thermally couple the semiconductor devices to the second plurality of heat exchange members via the second substrate.

In another aspect, a power module comprises a housing of electrically insulative material, the housing comprising an interior and an exterior; a first plurality of heat exchange members coupled to the housing; a second plurality of heat exchange members coupled to the housing and electrically isolated from the first plurality of heat exchange members; a first substrate of electrically and thermally conductive material received in the interior of the housing and thermally coupled to the first plurality of heat exchange members without any intervening thermally insulative structures; a second substrate of electrically and thermally conductive material received in the interior of the housing and thermally coupled to the second plurality of heat exchange members without any intervening thermally insulative structures, the second substrate electrically isolated from the first substrate; a third substrate received in the housing and electrically isolated from the first substrate, the third substrate electrically coupled to the second substrate via at least one wire bond; a first set of semiconductor devices comprising at least one transistor and at least one diode, each of the semiconductor devices of the first set surface mounted to the first substrate to electrically couple a first terminal of the semiconductor device to the first substrate and to thermally couple the semiconductor devices to the first plurality of heat exchange members via the first substrate, wherein a second terminal of the semiconductor devices of the first set of semiconductor devices is electrically coupled to the second substrate; and a second set of semiconductor devices comprising at least one transistor and at least one diode, each of the semiconductor devices of the second set surface mounted to the second substrate to electrically couple a first terminal of the semiconductor device to the second substrate and to thermally couple the semiconductor devices to the second plurality of heat exchange members via the second substrate, wherein a second terminal of the semiconductor devices of the second set of semiconductor devices is electrically coupled to the third substrate, the first and the second set of semiconductor devices forming a half bridge inverter.

In a further aspect, a power module comprises a housing; a first heat exchange loop; a first set of semiconductor devices comprising at least a first transistor and at least a first diode; a second set of semiconductor devices comprising at least a first transistor and a first diode, the first and the second sets of semiconductor devices electrically coupled as a half bridge inverter; first means for thermally coupling the first set of semiconductor devices to the first heat exchange loop without any intervening thermally insulative structures; second means for thermally coupling the second set of semiconductor devices to the first heat exchange loop without any intervening thermally insulative structures, the second means electrically isolated from the first means.

In yet a further aspect, a power module comprises a housing of electrically insulative material, the housing comprising an interior and an exterior; a first substrate of electrically and thermally conductive material received in the interior of the housing, the first substrate comprising a coupling structure to selectively electrically couple to a first pole of an external DC device located in the exterior; a second substrate of electrically and thermally conductive material received in the interior of the housing and electrically isolated from the first substrate; a third substrate received in the housing and electrically isolated from the first substrate, the third substrate electrically coupled to the second substrate via at least one wire bond, the third substrate comprising a coupling structure to selectively electrically couple to a second pole of the external DC device; a first set of semiconductor devices comprising at least one transistor and at least one diode, each of the semiconductor devices of the first set surface mounted to the first substrate to electrically couple a first terminal of the semiconductor device to the first substrate and to thermally couple the semiconductor devices to the first substrate, wherein a second terminal of the semiconductor devices of the first set of semiconductor devices is electrically coupled to the second substrate; and a second set of semiconductor devices comprising at least one transistor and at least one diode, each of the semiconductor devices of the second set surface mounted to the second substrate to electrically couple a first terminal of the semiconductor device to the second substrate and to thermally couple the semiconductor devices to the second substrate, wherein a second terminal of the semiconductor devices of the second set of semiconductor devices is electrically coupled to the third substrate, the first and the second set of semiconductor devices forming a half bridge inverter.

### BRIEF DESCRIPTION OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn, are not intended to convey any information regarding the actual shape of the particular elements, and have been solely selected for ease of recognition in the drawings.

FIG. 1 is a cross sectional view of a power module comprising a first, second and third substrates, a respective set of semiconductor components electrically and thermally coupled to the first and second substrates and wired as half bridge inverter, a respective plurality of heat exchange members thermally coupled to the first and second substrates without any intervening thermally insulative structures, and first and second heat exchange loops according to one illustrated embodiment.

FIG. 2 is a partial isometric view of one half bridge inverter of the power module of FIG. 1.

FIG. 3 is an electrical schematic diagram illustrating three half bridge inverters, one each for providing a respective one of three phases of an alternating current output.

FIG. 4 is isometric view of the power module of FIG. 1.

FIG. 5 is a cross sectional view of a power module comprising separate plates that carry the heat exchange members, the plates thermally coupled to the first and second substrates, according to another illustrated embodiment.

### DETAILED DESCRIPTION OF THE INVENTION

In the following description, certain specific details are set forth in order to provide a thorough understanding of various embodiments of the invention. However, one skilled in the art will understand that the invention may be practiced without these details. In other instances, well-known structures such as control systems including microprocessors and drive circuitry have not been shown or described in detail to avoid unnecessarily obscuring descriptions of the embodiments of the invention.

Unless the context requires otherwise, throughout the specification and claims which follow, the word “comprise” and variations thereof, such as, “comprises” and “comprising” are to be construed in an open, inclusive sense, that is as “including, but not limited to.”

The headings provided herein are for convenience only and do not interpret the scope or meaning of the claimed invention.

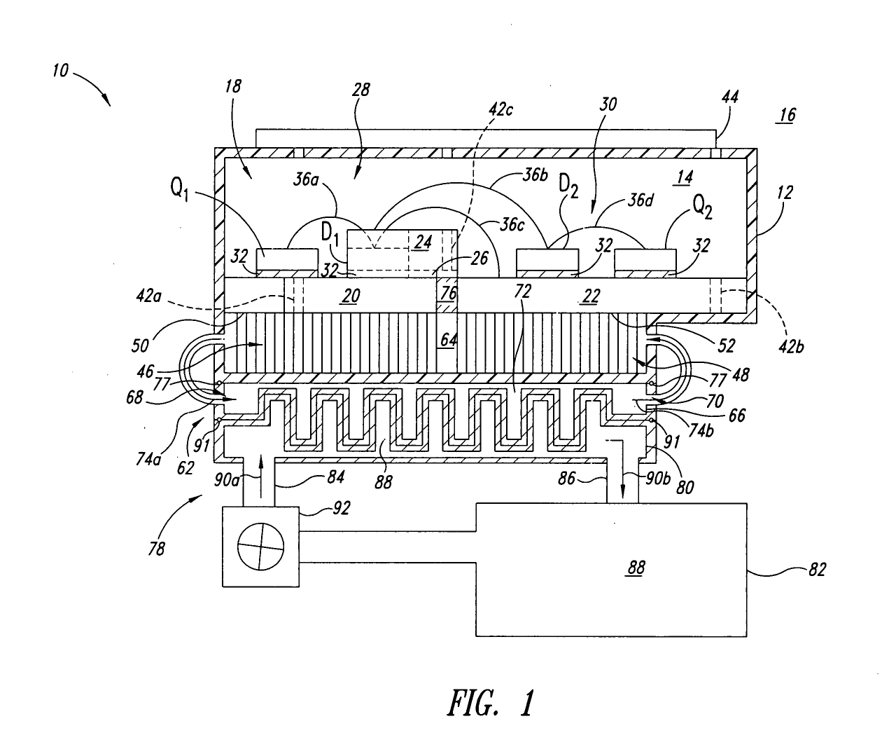

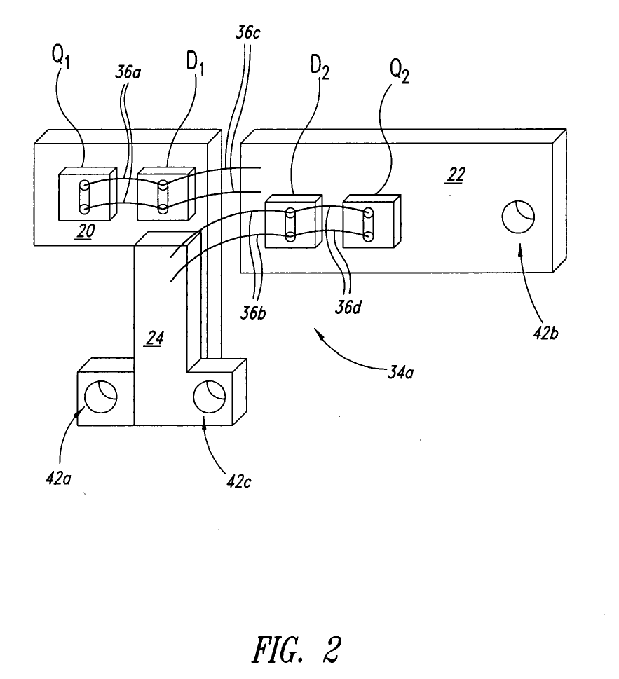

FIGS. 1 and 2 show a power module 10 according to one illustrated embodiment. The power module 10 comprises a housing 12 having an interior 14 and an exterior 16. The housing comprises an electrically insulating material. The power module 10 also comprises a power converter 18 received within the interior 14 of the housing 12. The power converter 18 may take a variety of forms, for example an AC→DC rectifier and/or DC→DC converter, although the illustrated embodiment takes the form of a DC→AC inverter for inverting a DC input to a three phase AC output.

The power converter 18 comprises a first substrate 20, second substrate 22, and third substrate 24. The substrates 20, 22, 24 are formed from one or more electrically and thermally conductive materials. For example, the material(s) may comprise copper or extruded aluminum, both of which are relatively inexpensive good electrical and thermal conductors. Each of the substrates 20, 22, 24 are electrically isolated from one another. For example, the first and second substrates 20, 22 are laterally spaced apart from one another, while the third substrate 24 is spaced relatively above the first substrate 20 and may be electrically isolated therefrom via one or more insulating materials 26, for example, a thin layer of Nomex® or Mylar® (e.g., 0.025-0.2 mm) available from E. I. Du Pont de Nemours and Company, with or without a silicon gel to prevent arcing.

The power converter 18 also comprises a first set of semiconductor devices 28 electrically and thermally coupled to the first substrate 20, and a second set of semiconductor devices 30 electrically and thermally coupled to the second substrate 22. For example, the first set of semiconductor devices 28 and the second set of semiconductor devices 30 each comprise a number of transistors and a number of diodes electrically coupled in anti-parallel or shunted across the transistors. As illustrated, the first set of semiconductor devices 28 comprises a “high” side (i.e., coupled to positive pole of DC power source) transistor Q₁ and diode D₁, while the second set of semiconductor devices 30 comprises a “low” side (i.e., coupled to negative pole of DC power source) transistor Q₂ and diode D₂. Each set of semiconductor devices 28, 30 may include additional transistor and diode pairs electrically coupled in parallel with the high side transistor Q₁ and diode D₁ and/or the low side transistor Q₂ and diode D₂, as may be suitable for the particular application (e.g., to accommodate the power ratings of the individual semiconductor devices).

The transistors Q₁,Q₂ may take a variety of forms, for example, insulated gate bipolar junction transistors (IGBTS) or metal oxide semiconductor transistors (MOSFETs). Such transistors Q₁,Q₂ are commercially available, individually, or in sets of two or six transistor switches. The transistors Q₁,Q₂ typically include the anti-parallel diodes D₁, D₂, which may or may not be an inherent portion of the fabricated semiconductor transistor Q₁, Q₂ structure. The transistors Q₁, Q₂ are essentially three element devices, comprising a pair of active elements (e.g., source/emitter, drain/collector) and a control element, (e.g., gate, base). While the terms emitters, collectors and base are occasionally used henceforth, those of skill in the art will recognize that such is for convenience only, and such use does not restrict the teachings or claims to IGBTs, but are also applicable to other types of transistors, for example, MOSFETs.

The transistors Q₁, Q₂ and associated diodes D₁, D₂ may be provided as unpackaged or bare dice. Each transistor Q₁, Q₂ bearing die is surface mounted to the corresponding one of the first and second substrates 20, 22, respectively, to electrically couple the collector of the transistor Q₁, Q₂ to the substrate 20, 22. The surface mounting may be via a solder 32, although other ways of mounting the transistors Q₁, Q₂ to the first and second substrates 20, 22 may be employed, for example, pressure assembly packaging, bolting or clamping. Surface mounting thermally couples substantially all of one surface of the transistor Q₁, Q₂ bearing die to the substrate 20, 22, respectively. This provides a maximum area for heat transfer from the transistors Q₁, Q₂ to the substrates 20, 22, respectively.

Alternatively, each of the transistors Q₁, Q₂ may be provided in a packaged form, typically comprising an electrically insulative body or case, and a heat sink extending from the case. For typical packaged transistors Q₁, Q₂, it is desirable to maximize the area of contact between the heat sink and the substrate. While the case provides the packaged transistors Q₁, Q₂ with enhanced environmental protection and consequently ease of handling, such transistors Q₁, Q₂ typically will not receive the full benefit of the heat transfer approach taught herein.

The diodes D₁, D₂ are two element devices, comprising a cathode and an anode. Like the transistors Q₁, Q₂, each of the diodes D₁, D₂ may be provided on the dice, and surface mounted to the corresponding one of the first and second substrates 20, 22, respectively, to electrically couple the cathode of the diode D₁, D₂ to the substrate 20, 22. The surface mounting may be via a solder 32, although other ways of mounting the transistors Q₁, Q₂ to the first and second substrates 20, 22 may be employed, for example, pressure assembly packaging, bolting or clamping. The surface mounting thermally couples the case of the diode D₁, D₂ to the substrate 20, 22, respectively.

Alternatively, each of the diodes D₁, D₂ may be formed as part of the packaged transistors Q₁, Q₂, as discussed above.

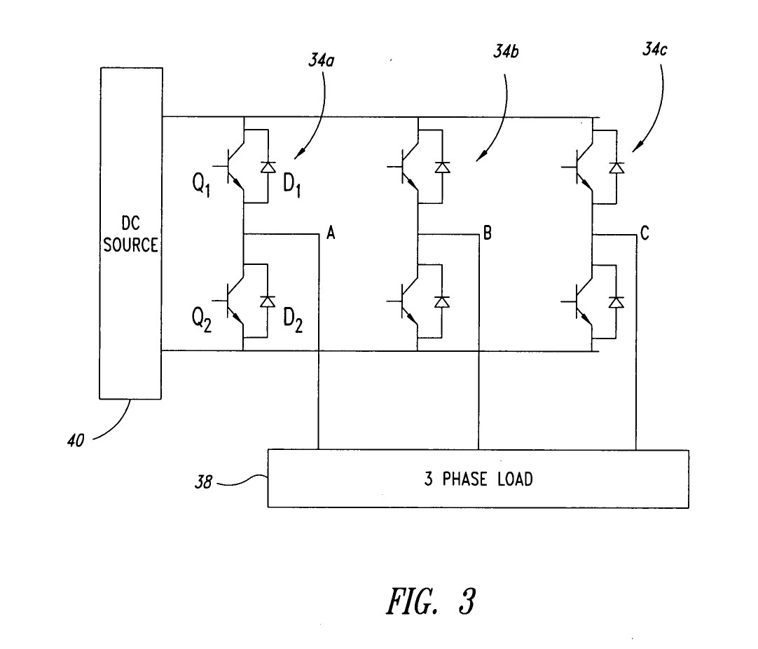

The emitter of the transistor Q₁, and the anode of the diode D₁ are electrically coupled to the second substrate 22 and the emitter of the transistor Q₂, and the anode of the diode D₂ are electrically coupled to the third substrate 24 to form a half bridge inverter circuit 34a (shown in FIG. 2). The electrical coupling may, for example, be made using one or more wire bonds 36a-36d. Note that only one wire bond 36a-36d is illustrated for each electrical coupling for clarity of presentation, although in practice the electrical coupling will employ a sufficient number of wire bonds 36a-36d to carry the anticipate power with some margin of error. The half bridge inverter 34a is illustrated in FIG. 3, along with two other half bridge inverters 34b, 34c, also housed in the housing 12, each half bridge inverter 34a-34c providing one phase of a three phase AC output to a three phase AC load 38 from a DC power source 40. These other half bridge inverters 34b, 34c may employ a similar construction to that of the half bridge inverter 34a shown in FIGS. 1 and 2.

Returning to FIGS. 1 and 2, the power converter 18 may employ any number and type of electrical and electronic components suitable for the particular application. The power converter 18 may, for example, comprise capacitors and/or inductors in addition to the transistors Q₁, Q₂ and diodes D₁, D₂ discussed above.

Each of the first, second and third substrates 20, 22, 24, respectively, may include a coupling structure 42a, 42b, 42c to electrically couple the first and third substrates 20, 24 to the external DC power source 40 (FIG. 3) and to electrically couple the second substrate 22 to an external three phase AC load 38 (FIG. 3) or single or poly phase of an external load. The coupling structure 42a, 42b, 42c may, for example, comprise one or more holes formed in or through the substrate 20, 22, 24, respectively. The holes may, or may not, be threaded. The holes may, or may not include sleeves or bushings to enhance structural strength and/or to provide suitable threads.

Optionally, the power module 10 may further comprise, or be coupled to a gate drive board 44. The gate drive board 44 is electrically coupled to the base or gates of the transistors Q₁, Q₂ to supply control signals thereto for operating the transistors Q₁, Q₂. The gate drive board 44 may be electrically coupled to the base or gates of the transistors Q₁, Q₂ via wire bonds (not shown) or other electrical connections. Gate drive circuits are known in the art and so will not be discussed in further detail.

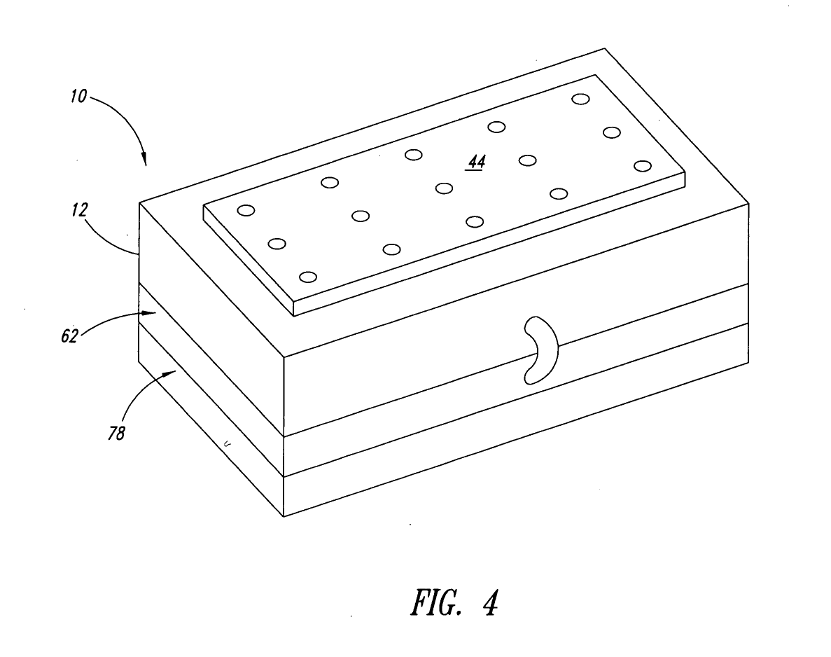

FIG. 4 shows the housing 12 and optional gate drive board 44 of the power module 10, according to one illustrated embodiment where the power module 10 is configured as a DC→AC inverter for providing a three phase AC output to a load 38 (FIG. 3) from an input from a DC power source 40 (FIG. 3). The housing 12 comprises a number of apertures for making external connections between the DC power source 40 and the first and third substrates 20, 24, and between the second substrate 22 and the three phase AC load 38. The first and third substrates 20, 24 thus serve as bus bars for making external connections to the positive and negative poles of the DC power source 40, while the second substrate 22 serves as a phase terminal for providing AC power to the three-phase AC load 38.

While two openings are shown for making the connections to the DC power source 40 for each half bridge, the power module 10 may comprise additional bus bar structures, such as conductive members (not shown) that extend from the first and third substrates 20, 24, out of the openings. Such conductive members may be integral or discrete with the substrates 20, 24; Some exemplary additional bus bar structures which may be suitable are taught in commonly assigned U.S. application Ser. Nos. 09/882,708 and 09/957,047 both filed Jun. 15, 2001. Such auxiliary bus bar structures may facilitate external electrical connections and may further facilitate the sealing of the housing 12 by filling the openings in the housing with or without a sealant, thereby enhancing environmental protection. However auxiliary bus bar structures will likely require additional materials and introduce complexity in the manufacturing process, and thus disadvantageously increase costs.

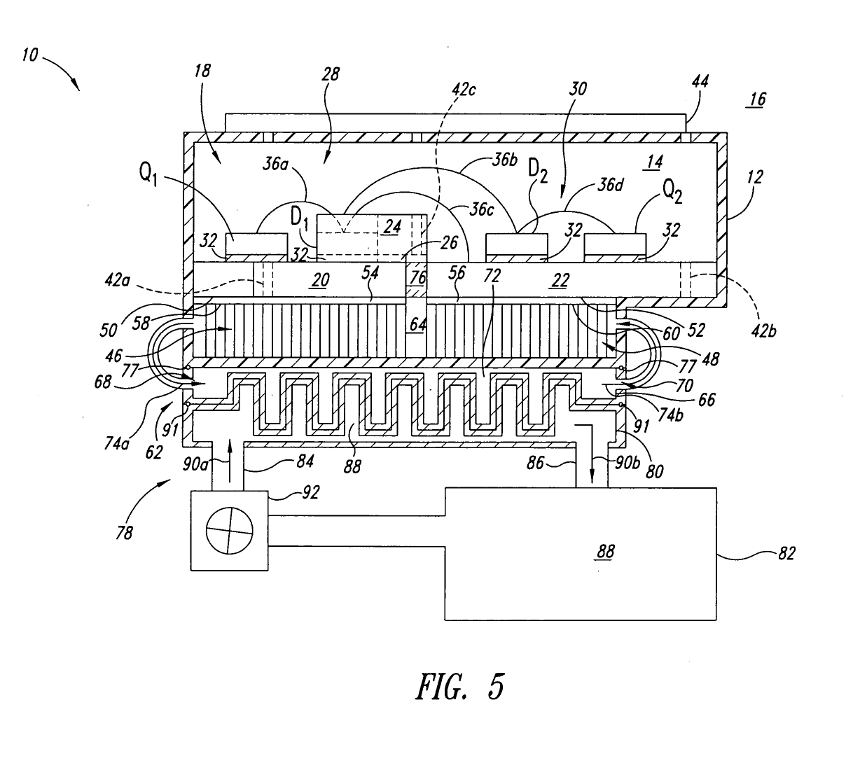

The power module 10 may include heat transfer structure, discussed immediately below with reference to FIGS. 1 and 5.

The first and second substrates 20, 22 are thermally coupled to first and second pluralities of heat exchange members 46, 48, respectively. The heat exchange members 46, 48 may take the form of fins, pins, channels or other structures that increase the amount of surface area over that of bottom surfaces 50, 52 of the first and second substrates 20, 22. The heat exchange members 46, 48 may be integrally formed with the respective first and second substrates 20, 22, for example, by extruding, machining or casting, or may be attached thereto. For example, the heat exchange members 46, 48 may be welded directly to the bottom surface 50, 52 of the first and second substrates 20, 22, or may be mounted into complimentary retaining structures formed on the bottom surfaces 50, 52 of the first and second substrates 20, 22, for example, by press fitting, shrink fitting and/or soldering.

Alternatively, as illustrated in FIG. 5, the heat exchange members 46, 48 may be associated with respective first and second plates 54, 56, which are thermally coupled to respective ones of the first and second substrates 20, 22. The heat exchange members 46, 48 may be integrally formed with the plates 54, 56, for example, by extruding, machining or casting. Alternatively, the heat exchange members 46, 48 may be mounted to bottom surfaces 58, 60 of the plates 54, 56. For example, the heat exchange members 46, 48 may be soldered directly to the bottom surfaces 58, 60 of the plates 54, 56, or may be mounted into complimentary retaining structures formed on the bottom surfaces 58, 60 of the first and second plates 54, 56, for example, by press fitting, shrink fitting and/or soldering.

With continuing reference to FIGS. 1 and 5, the power module may comprise, or may be coupled to a first heat exchange loop 62. The first heat exchange loop 62 comprises a first chamber 64, a first reservoir 66, an inlet 70 and an outlet 68 for circulating a first heat transfer medium 72 through the first chamber 64 and about the heat exchange members 46, 48, as illustrated by arrows 74a, 74b. An insulator 76 may be received between the first and second substrates 20, 22 to enclose the first chamber 64, separating the semiconductor devices 28, 30 from the first heat transfer medium 72, but without intervening between the semiconductor devices 28, 30 and the heat transfer members 46, 48. The first heat exchange loop 62 may include a ring or seal 77 to seal the first chamber 64 with respect to the bottom surfaces 50, 52 of the first and second substrates 20, 22 or with respect to the bottom surfaces 58, 60 of the plates 54, 56. The first heat transfer medium 72 may take a variety of forms, for example, a fluid such as a liquid, gas, or a fluid that changes phases between liquid and gas as the fluid circulates through different portions of the first heat exchange loop 62. The gas may, for example, take the form of air. The circulation may be passive or active, for example relying on a pump, compressor or fan (not shown) to actively circulate the first heat transfer medium 72.

While the first heat exchange loop 62 is illustrated as comprising a single first chamber 64 and first reservoir 66, other embodiments may employ separate and distinct sub-heat exchange loops, where one sub-loop circulates heat exchange medium past the first plurality of heat exchange members 46 and a another distinct sub-loop circulates heat exchange medium past the second plurality of heat exchange members 48. This may provide more efficient heat transfer, and/or may reduce any possibility of shorting where the heat exchange medium may act as a conductor (e.g., metal shavings or filings become suspended or dissolved in the heat exchange medium).

The power module 10 may further comprise, or may be coupled to a second heat exchange loop 78. The second heat exchange loop 78 comprises a second chamber 80, a second reservoir 82, an inlet 84 and an outlet 86 for circulating a second heat transfer medium 88, as illustrated by arrows 90a, 90b. The second heat transfer medium 88 may take a variety of forms, for example, a fluid such as a liquid, gas, or a fluid that changes phase as the fluid circulates through different portions of the second heat exchange loop 78. The circulation may be passive or active, for example relying on a pump, compressor or fan 92 to actively circulate the second heat transfer medium 88.

The first and/or second chambers 64, 80 and/or the first and/or second reservoirs 66, 82 may be formed from a single piece of material in a conventional manner, such as extruded or machined aluminum, or may be comprised of separate components assembled together in a conventional manner. The second heat exchange loop 78 may include a ring or seal 91 to seal the second chamber 80 with respect to the first reservoir 66.

While FIGS. 1 and 5 illustrate exemplary connections between the first and third substrates 20, 24 and the DC power source 40 (FIG. 3), the power module 10 may include additional or alternative bus bar structures for making these connections. For example, the power module may comprise two additional parallel bus bar structures separated by bus bar insulation. Each additional bus bar structure comprises at least one terminal externally accessible for making external connections. For example, a portion of each of the additional bus bar structures extends out of the housing 12. One of the additional bus bar structures may be electrically coupled to each of the first and third substrates 20, 24, for example, using a screw or bolt received in the holes 42a, 42c, or via other fasteners. Alternatively, one or more wire bonds electrically connect one of the additional bus bar structures to the first substrate 20 and one or more wire bonds electrically connect the other additional bus bar structure to the third substrate 24. A suitable structure is disclosed in the applications incorporated by reference, below.

Further, while FIGS. 1 and 5 illustrate exemplary connections between the second substrates 22 and the phase of the three phase AC load 38 (FIG. 3), the power module 10 may include additional or alternative structures for making these connections. An additional phase terminal structure accessible from the exterior 16 (FIG. 1) of the housing 12 may be electrically coupled to the second substrate 22, for example, using a screw or bolt received in the hole 42b, or via other fasteners. Alternatively, one or more wire bonds may electrically connect the second substrate 22 to the additional phase terminal structure to make electrical connections to one phase of the three phase load 38 (FIG. 3).

The above described structures eliminate an insulator and two interfaces from the thermal path of conventional designs, thereby increasing the efficiency of heat transfer from the semiconductor devices, thereby enhancing the efficiency, reliability and cost competitiveness of the power module. The above described structures integrate the bus bar and/or phase terminal function and the semiconductor mounting functions into single structures (e.g., first substrate 20 serves as the positive DC bus bar and as the physical, electrical, and thermal coupling structure for the high-side semiconductor devices 28; second substrate 22 serves as the AC phase terminal and as the physical, electrical, and thermal coupling structure for the low-side semiconductor devices 30), simplifying design, reducing parts count, and consequently lowering costs, volume and/or weight.

Although specific embodiments of and examples of the present power modules and methods are described herein for illustrative purposes, various equivalent modifications can be made without departing from the spirit and scope of the invention, as will be recognized by those skilled in the relevant art. The teachings provided herein can be applied to power module and power converters, rectifiers and/or inverters not necessarily the exemplary three phase half bridge power module generally described above. For example, it will be apparent to those of skill in the art from the above teachings that the semiconductor devices may be configured as full bridges, half bridges, and/or H-bridges, as suits the particular application. It will also be apparent that the first and third substrates 20, 24, respectively, may be electrically coupled to a DC load or a DC device that constitutes a DC source at some times and a DC load at other times (e.g., regeneration). Similarly, the second substrate 22 may be electrically coupled to an AC source, or an AC device that constitutes an AC load at some times and an AC source at other times (e.g., regeneration).

While elements may be described herein and in the claims as “positive” or “negative” such denomination is relative and not absolute. Thus, an element described as “positive” is shaped, positioned and/or electrically coupled to be at a higher relative potential than elements described as “negative” when the power module 10 is coupled to a power source. “Positive” elements are typically intended to be coupled to a positive terminal of a power source, while “negative” elements are intended to be coupled to a negative terminal or ground of the power source. Generally, “positive” elements are located or coupled to the high side of the power module 10 and “negative” elements are located or coupled to the low side of the power module 10.

The power modules described above may employ various methods and regimes for operating the power module 10 and for operating the semiconductor devices (e.g., transistors Q₁, Q₂). The particular method or regime may be based on the particular application and/or configuration, and basic methods and regimes will be apparent to one skilled in the art.

The various embodiments described above can be combined to provide further embodiments. All of the above U.S. patents, patent applications and publications referred to in this specification, including but not limited to: Ser. Nos. 60/233,992; 60/233,993; 60/233,994; 60/233,995 and 60/233,996, each filed Sep. 20, 2000; Ser. No. 09/710,145, filed Nov. 10, 2000; Ser. Nos. 09/882,708 and 09/957,047, both filed Jun. 15, 2001; Ser. Nos. 09/957,568 and 09/957,001, both filed Sep. 20, 2001; Ser. No. 10/109,555, filed Mar. 27, 2002; Ser. No. 60/471,387, filed May 16, 2003, are incorporated herein by reference, in their entirety. Aspects of the invention can be modified, if necessary, to employ systems, circuits and concepts of the various patents, applications and publications to provide yet further embodiments of the invention.

These and other changes can be made to the invention in light of the above-detailed description. In general, in the following claims, the terms used should not be construed to limit the invention to the specific embodiments disclosed in the specification and the claims, but should be construed to comprise all power modules, rectifiers, inverters and/or converters that operate or embody the limitations of the claims. Accordingly, the invention is not limited by the disclosure, but instead its scope is to be determined entirely by the following claims.

1. A power module, comprising:
a housing of electrically insulative material, the housing comprising an interior and an exterior;
a first plurality of heat exchange members coupled to the housing;
a second plurality of heat exchange members coupled to the housing and electrically isolated from the first plurality of heat exchange members;
a first substrate of electrically and thermally conductive material received in the interior of the housing and thermally coupled to the first plurality of heat exchange members without any intervening thermally insulative structures;
a second substrate of electrically and thermally conductive material received in the interior of the housing and thermally coupled to the second plurality of heat exchange members without any intervening thermally insulative structures, the second substrate electrically isolated from the first substrate;
a first set of semiconductor devices each comprising at least a first terminal and a second terminal, each of the semiconductor devices of the first set surface mounted to the first substrate to electrically couple the first terminal of the semiconductor device to the first substrate and to thermally couple the semiconductor devices to the first plurality of heat exchange members via the first substrate; and
a second set of semiconductor devices each comprising at least a first terminal and a second terminal, each of the semiconductor devices of the second set surface mounted to the second substrate to electrically couple the first terminal of the semiconductor device to the second substrate and to thermally couple the semiconductor devices to the second plurality of heat exchange members via the second substrate.

2. The power module of claim 1, further comprising:
a third substrate received in the housing and electrically isolated from the first substrate, the third substrate electrically coupled to the second substrate via at least one wire bond.

3. The power module of claim 2 wherein the first, the second and the third substrates each comprise a coupling structure to electrically couple the first and the third substrates to an external power source and to electrically couple the second substrate to an external load.

4. The power module of claim 3 wherein the coupling structures comprise a respective hole formed through each of the first, the second, and the third substrates.

5. The power module of claim 3 wherein the coupling structures comprise a respective threaded hole formed through the first, the second, and the third substrates.

6. The power module of claim 2 wherein the second terminals of the semiconductor devices of the second set of semiconductor devices are electrically coupled to the third substrate by at least one wire bond and the second terminals of the semiconductor devices of the first set of semiconductor devices are electrically coupled to the second substrate via at least one wire bond.

7. The power module of claim 6 wherein the first set of semiconductor devices comprises at least one transistor and one diode coupled in anti-parallel with the transistor and the second set of semiconductor devices comprises at least one transistor and one diode coupled in anti-parallel with the transistor.

8. The power module of claim 1 wherein the first set of semiconductor devices comprises at least one transistor selected from the group consisting of an insulated gate bipolar transistor and a metal oxide semiconductor transistor.

9. The power module of claim 1 wherein the first and the second plurality of heat exchange members are received in the interior of the housing.

10. The power module of claim 1, further comprising:
a first heat transfer loop carrying a first heat transfer medium in thermal contact with the first and the second plurality of heat exchange members.

11. The power module of claim 10, further comprising:
a second heat transfer loop carrying a second heat transfer medium thermally coupled to the first heat transfer medium.

12. The power module of claim 11, further comprising:
at least one of a fan, a heat exchanger and a pump operable to circulate at least one of the first and the second heat transfer mediums in the respective one of the first and the second heat transfer loops.

13. A power module, comprising:
a housing of electrically insulative material, the housing comprising an interior and an exterior;
a first plurality of heat exchange members coupled to the housing;
a second plurality of heat exchange members coupled to the housing and electrically isolated from the first plurality of heat exchange members;
a first substrate of electrically and thermally conductive material received in the interior of the housing and thermally coupled to the first plurality of heat exchange members without any intervening thermally insulative structures;
a second substrate of electrically and thermally conductive material received in the interior of the housing and thermally coupled to the second plurality of heat exchange members without any intervening thermally insulative structures, the second substrate electrically isolated from the first substrate;
a third substrate received in the housing and electrically isolated from the first substrate, the third substrate electrically coupled to the second substrate via at least one wire bond;
a first set of semiconductor devices comprising at least one transistor and at least one diode, each of the semiconductor devices of the first set surface mounted to the first substrate to electrically couple a first terminal of the semiconductor device to the first substrate and to thermally couple the semiconductor devices to the first plurality of heat exchange members via the first substrate, wherein a second terminal of the semiconductor devices of the first set of semiconductor devices is electrically coupled to the second substrate; and
a second set of semiconductor devices comprising at least one transistor and at least one diode, each of the semiconductor devices of the second set surface mounted to the second substrate to electrically couple a first terminal of the semiconductor device to the second substrate and to thermally couple the semiconductor devices to the second plurality of heat exchange members via the second substrate, wherein a second terminal of the semiconductor devices of the second set of semiconductor devices is electrically coupled to the third substrate, the first and the second set of semiconductor devices forming a half bridge inverter.

14. The power module of claim 13 wherein the first, the second and the third substrates each comprise a coupling structure to electrically couple the first and the third substrates to at least one of an external DC load and an external DC source and to electrically couple the second substrate to at least one of an external AC source and an external AC load.

15. The power module of claim 13 wherein the first plurality of heat exchange members comprises a plurality of fins extending from a first metal plate and the first substrate is soldered directly to the first metal plate.

16. The power module of claim 13, further comprising:
a first heat transfer loop carrying a first heat transfer medium in thermal contact with the first and the second plurality of heat exchange members; and
a second heat transfer loop carrying a second heat transfer medium thermally coupled to the first heat transfer medium.

17. A power module, comprising:
a housing;
a first heat exchange loop;
a first set of semiconductor devices comprising at least a first transistor and at least a first diode;
a second set of semiconductor devices comprising at least a first transistor and a first diode, the first and the second sets of semiconductor devices electrically coupled as a half bridge inverter;
first means for thermally coupling the first set of semiconductor devices to the first heat exchange loop without any intervening thermally insulative structures;
second means for thermally coupling the second set of semiconductor devices to the first heat exchange loop without any intervening thermally insulative structures, the second means electrically isolated from the first means.

18. The power module of claim 17 wherein the first means comprises a first substrate soldered to a first plate from which a plurality of heat exchange members project and to which the first set of semiconductor devices is electrically and thermally coupled.

19. The power module of claim 18 wherein the second means comprises a second substrate soldered to a second plate from which a second plurality of heat exchange members project and to which the second set of semiconductor devices is electrically and thermally coupled, the second substrate electrically isolated from the first substrate.

20. The power module of claim 19 wherein the first substrate comprises a first coupling structure, the second substrate comprises a second coupling structure, and further comprising:
a third substrate electrically coupled to the second substrate via a number of wire bonds.

21. A power module, comprising:
a housing of electrically insulative material, the housing comprising an interior and an exterior;
a first substrate of electrically and thermally conductive material received in the interior of the housing, the first substrate comprising a coupling structure to selectively electrically couple to a first pole of an external DC device located in the exterior;
a second substrate of electrically and thermally conductive material received in the interior of the housing and electrically isolated from the first substrate;
a third substrate received in the housing and electrically isolated from the first substrate, the third substrate electrically coupled to the second substrate via at least one wire bond, the third substrate comprising a coupling structure to selectively electrically couple to a second pole of the external DC device;
a first set of semiconductor devices comprising at least one transistor and at least one diode, each of the semiconductor devices of the first set surface mounted to the first substrate to electrically couple a first terminal of the semiconductor device to the first substrate and to thermally couple the semiconductor devices to the first substrate, wherein a second terminal of the semiconductor devices of the first set of semiconductor devices is electrically coupled to the second substrate; and
a second set of semiconductor devices comprising at least one transistor and at least one diode, each of the semiconductor devices of the second set surface mounted to the second substrate to electrically couple a first terminal of the semiconductor device to the second substrate and to thermally couple the semiconductor devices to the second substrate, wherein a second terminal of the semiconductor devices of the second set of semiconductor devices is electrically coupled to the third substrate, the first and the second set of semiconductor devices forming a half bridge inverter.

22. The power module of claim 21 wherein the second substrate comprises a coupling structure to selectively electrically couple to an AC device external to the housing.

23. The power module of claim 21, further comprising:
a first plurality of heat exchange members coupled to the housing;
a second plurality of heat exchange members coupled to the housing and electrically isolated from the first plurality of heat exchange members, wherein the first substrate is thermally coupled to the first plurality of heat exchange members without any intervening thermally insulative structures and the second substrate is thermally coupled to the second plurality of heat exchange members without any intervening thermally insulative structures.

24. The power module of claim 23 wherein the surface mounting of the first set of semiconductor devices thermally couples each of the semiconductor devices in the first set of semiconductor devices to the first plurality of heat exchange members via the first substrate, and wherein the surface mounting of the second set of semiconductor devices thermally couples each of the semiconductor devices in the second set of semiconductor devices to the second plurality of heat exchange members via the second substrate.
